(19) United States
(12) Patent Application Publication
(10) Pub. No.: US 2014/0027160 A1
(43) Pub. Date: Jan. 30, 2014

(54) PRINTED CIRCUIT BOARD AND FABRICATING METHOD THEREOF

(71) Applicants: Seok Yoon HONG, Suwon (KR); Kyung In Kang, Suwon (KR)

(72) Inventors: Seok Yoon HONG, Suwon (KR); Kyung In Kang, Suwon (KR)

(21) Appl. No.: 13/619,254

(22) Filed: Sep. 14, 2012

(30) Foreign Application Priority Data
Jul. 27, 2012 (KR) 10-2012-0082399

(51) Int. Cl. H05K 1/09; B05D 5/12; H05K 1/02

(52) U.S. Cl. 174/257; 174/250; 427/97.3

(57) ABSTRACT

There is provided a printed circuit board including: a core substrate; a solder mask selectively covering one surface of the core substrate; an open region of the solder mask including a portion of a surface of the core substrate and partitioned by the solder mask; a ball land formed on the open region of the solder mask; and a barrier formed between the ball land and the solder mask.

### CROSS-REFERENCE TO RELATED APPLICATIONS

This application claims the priority of Korean Patent Application No. 10-2012-0082399 filed on Jul. 27, 2012, in the Korean Intellectual Property Office, the disclosure of which is incorporated herein by reference.

### BACKGROUND OF THE INVENTION

1. Field of the Invention

The present invention relates to a printed circuit board having high reliability and a fabricating method thereof.

2. Description of the Related Art

Recently, in the electronics industry, a mounting technology using a printed circuit board capable of implementing high densification, high precision, and high integration in mounting components in order to allow electronic devices to be miniaturized and thinned has been used. The printed circuit board as described above has been used in various devices, such as in a factory automation (FA) machine, an office automation (OA) machine, a communications device, a broadcasting device, a portable computer, and the like.

Particularly, in accordance with the trend for slimness and lightness in electronic products according to the miniaturization, high densification, packaging, and personal portability thereof, miniaturization and high densification of the printed circuit board have also been conducted. In addition, recently, in accordance with the development of chip size package (CSP) technologies such as a ball grid array (BGA), a tape carrier package (TCP), and the like, interest in a high density printed circuit board on which chips may be mounted has been gradually increasing.

Meanwhile, recently, in order to reduce a product process cost and a process time required therefor, a product to which a molded underfill (MUF) process is applied has been increasingly provided.

However, in the MUF package, due to a difference in a coefficient of thermal expansion, a difference in a flexural modulus, or the like, between an epoxy molding compound (EMC) and a solder resist (SR), a defect such as an SR crack, or the like, often occurs.

### RELATED ART DOCUMENT

Japanese Patent Laid-Open Publication No. 2001-298117
Japanese Patent Laid-Open Publication No. 2004-083192

### SUMMARY OF THE INVENTION

An aspect of the present invention provides a printed circuit board having high reliability and a fabricating method thereof.

According to an aspect of the present invention, there is provided a printed circuit board including: a core substrate; a solder mask selectively covering one surface of the core substrate; an open region of the solder mask including a portion of a surface of the core substrate and partitioned by the solder mask; a ball land formed on the open region of the solder mask; and a barrier formed between the ball land and the solder mask.

The ball land may include copper (Cu).

A height of the barrier may be greater than that of the ball land and less than that of the solder mask.

One side of the barrier may contact the ball land and the other side thereof may contact the solder mask.

The height of the barrier may be 10 μm or less.

The barrier may include a conductive metal.

According to another aspect of the present invention, there is provided a printed circuit board including: a core substrate; a solder mask formed on one surface of the core substrate; a ball land formed on one surface of the core substrate; and a barrier formed between the solder mask and the ball land and including a conductive metal.

A height of the barrier maybe greater than that of the ball land and less than that of the solder mask.

According to another aspect of the present invention, there is provided a method of fabricating a printed circuit board, including: preparing a core substrate; forming a solder mask and a ball land on one surface of the core substrate; and applying a conductive paste between the solder mask and the ball land to form a barrier.

The conductive paste may include at least one of a copper (Cu) powder and a silver (Ag) powder.

The conductive paste may have a viscosity of 10,000 to 30,000 cP.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are views showing a solder mask defined (SMD)-type ball land structure;

FIGS. 2A and 2B are views showing a non solder mask defined (NSMD)-type ball land structure;

FIGS. 3A and 3B are views showing a ball land structure according to an embodiment of the present invention;

FIG. 4 is a view showing a stress progress direction in a printed circuit board according to the embodiment of the present invention;

FIG. 5 is a flow chart schematically showing a method of fabricating a printed circuit board according to the embodiment of the present invention; and

FIGS. 6A through 6C are cross-sectional views for describing the method of fabricating a printed circuit board of FIG. 5.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

As used herein, the singular forms “a” “an” and “the” are intended to include the plural forms as well, unless the context clearly indicates otherwise. In addition, unless explicitly described otherwise, “comprising” any components will be understood to imply the inclusion of other components but not the exclusion of any other components.

In the drawings, the shapes and dimensions of elements maybe exaggerated for clarity, and the same reference numerals will be used throughout to designate the same or like elements.

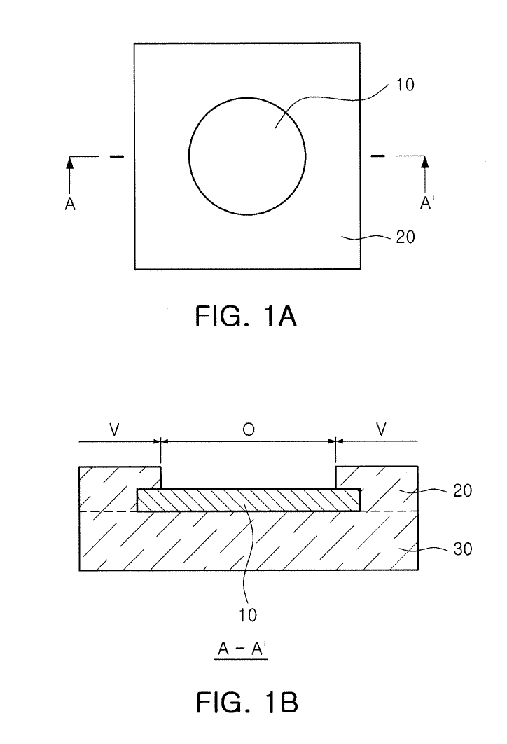

FIGS. 1A and 1B are views showing a solder mask defined (SMD)-type ball land structure.

FIG. 1A is a plan view showing the SMD-type ball land structure. FIG. 1B is a cross-sectional view taken along line A-A′ of FIG. 1A.

Referring to FIGS. 1A and 1B, a ball land 10 may be formed on one surface of a substrate 30. In addition, a solder mask 20 may be applied to one surface of the substrate 30.

On a plane, a portion in which the solder mask 20 is formed will be defined as a cover region V of the solder mask. In addition, on the plane, a region in which the solder mask 20 is not formed will be defined as an open region O of the solder mask.

The ball land 10 may be provided to fuse the solder ball therewith. For example, the solder ball may be fused to the ball land 10 and an external element may be connected to the ball land 10 through the solder ball.

Most regions except for an edge of the ball land 10 may be exposed to the outside through the open region O of the solder mask. Therefore, in the SMD-type ball land structure, the edge region of the ball land 10 may also be covered by the solder mask 20.

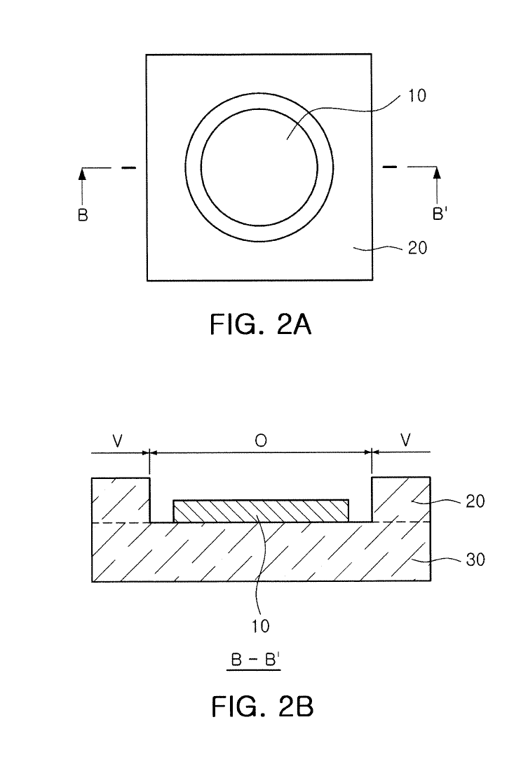

FIGS. 2A and 2B are views showing a non solder mask defined (NSMD) -type ball land structure.

FIG. 2A is a plan view showing the NSMD-type ball land structure. FIG. 2B is a cross-sectional view taken along line B-B′ of FIG. 2A.

Referring to FIGS. 2A and 2B, a ball land 10 may be formed on one surface of a substrate 30. In addition, a solder mask 20 may be applied to one surface of the substrate 30.

As described above, on a plane, a portion in which the solder mask 20 is formed will be defined as a cover region V of the solder mask. In addition, on the plane, a region in which the solder mask 20 is not formed will be defined as an open region O of the solder mask.

In the NSMD-type ball land structure, the ball land 10 may be formed on a portion of a surface of the substrate 30 corresponding to the open region O. That is, in the NSMD-type ball land structure, the ball land 10 may not be covered by the solder mask 20 at all.

The SMD-type ball land structure and the NSMD-type ball land structure may have the following differences therebetween.

In the SMD-type ball land structure, the solder mask 20 covers the edge of the ball land 10. Therefore, the SMD-type ball land structure is relatively resistant to stress applied from the outside. However, in the SMD-type ball land structure, when the solder ball is formed on the ball land 10, it may have a ball neck shape, such that bonding reliability of the solder ball may be degraded.

On the other hand, in the NSMD-type ball land structure, the ball land 10 is entirely exposed. Therefore, the solder ball does not have the ball neck shape, such that the NSMD-type ball land structure is relatively resistant to stress applied from the inside.

In other words, in the NSMD-type ball land structure, cracking occurring in the solder mask 20 may be reduced. The reason for this is that the NSMD-type ball land structure may reduce stress occurring at the time of mounting the solder ball.

However, in the NSMD-type ball land structure, since the ball land is completely exposed, bonding force between the ball land 10 and a core substrate 30 may be weakened. As a result, the NSMD-type ball land structure is vulnerable to a delamination phenomenon. For example, since a flux between the solder mask 20 and the ball land 10 may not be easily removed, delamination may be generated on an interface between an EMC and the solder mask by the flux. Further, in the NSMD-type ball land structure, at the time of performing a reflow, the solder may be sunk, such that a gap between a mounted chip and the core substrate 30 may be reduced.

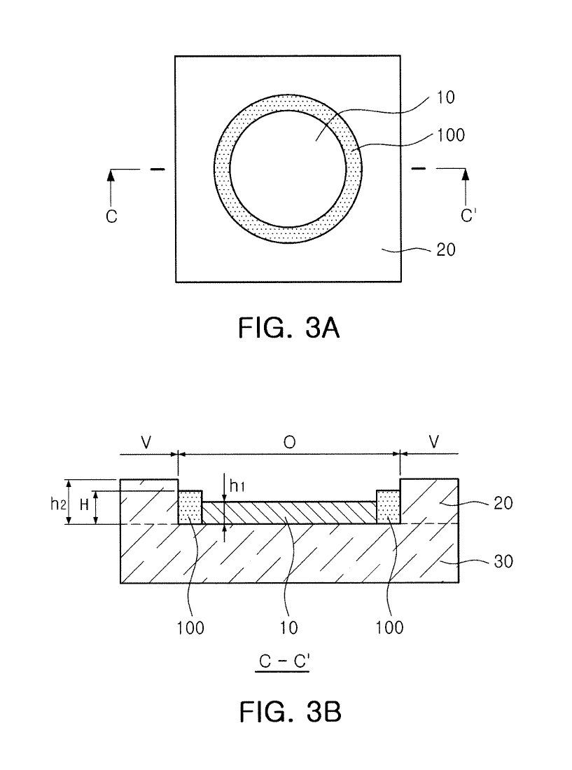

FIGS. 3A and 3B are views showing a ball land structure according to an embodiment of the present invention.

FIG. 3A is a plan view showing the ball land structure according to the embodiment of the present invention, and FIG. 3B is a cross-sectional view taken along line C-C′ of FIG. 3A.

Referring to FIGS. 3A and 3B, a ball land 10 may be formed on one surface of a substrate 30. The ball land 10 may have a circular shape on a plane.

In addition, a solder mask 20 may be applied to one surface of the substrate 30.

In this case, the ball land 10 and the solder mask 20 may be formed on one surface of the substrate 30 so as to be spaced apart from each other by a predetermined interval.

As described above, on the plane, a portion in which the solder mask 20 is formed will be defined as a cover region V of the solder mask. In addition, on the plane, a region in which the solder mask 20 is not formed will be defined as an open region O of the solder mask. In other words, a region partitioned by the solder mask in one surface of the substrate 30 may be the open region of the solder mask. In this case, the open region of the solder mask may have a circular shape on the plane.

The ball land 10, which is provided to fuse the solder ball, may include a conductive metal. The ball land 10 may include copper (Cu), and the like.

According to the embodiment of the present invention, the ball land 10 may be formed on a portion of the open region O of the solder mask. That is, the ball land 10 may not be covered by the solder mask 20 at all.

The ball land 10 and the solder mask 20 may have a barrier 100 formed therebetween. For example, the barrier 100 may be formed by applying a conductive paste to a region between the ball land 10 and the solder mask 20 and then being subjected to processes such as a printing process, a dispensing process, and the like. The conductive paste may include a metal powder having relatively high conductivity. For example, the metal powder may be a copper (Cu) powder, a silver (Ag) powder, and the like.

In addition, a thixotropic index of the conductive paste may be 1.5 to 2.0. The reason is that in the case in which the thixotropic index of the conductive paste corresponds to the above-mentioned range, process efficiency in the printing and dispensing processes may be improved.

For example, in the case in which the thixotropic index of the conductive paste is outside of the above-mentioned range, a form of the barrier may not be maintained in the printing and dispensing processes using the conductive paste.

Meanwhile, the barrier 100 may be formed of the conductive paste including the metal powder having high conductivity, thereby reducing bonding resistance with the solder ball. Bonding resistance refers to a resistance value occurring at the time of bonding the solder ball to the ball land 10.

Meanwhile, a height (H) of the barrier 100 may be greater than a height (h1) of the ball land 10.

The reason is that in the case in which the height (H) of the barrier 100 is less than the height (h1) of the ball land 10, when the core substrate 30 is filled with the epoxy molding compound (EMC), voids may occur in regions having a height lower than the height (h1) of the ball land.

Meanwhile, the height (H) of the barrier 100 maybe lower than a height (h2) of the solder mask 20.

The reason is that in the case in which the height (H) of the barrier is greater than the height (h2) of the solder mask, a defect may occur in a solder printing process and a cleaning process.

For example, in the case in which the height of the barrier 100 is excessively high, the solder ball which needs to be formed on the ball land 10 may not be accurately formed on the ball land 10 due to the presence of the barrier 100.

That is, the height (H) of the barrier is appropriately adjusted, whereby bonding properties between the solder ball and the ball land 10 may be improved.

The height (H) of the barrier may be 10 μm or less.

As shown in FIGS. 3A and 3B, an inner side of the barrier 100 may contact the ball land 10. In addition, an outer side of the barrier 100 may contact the solder mask 20.

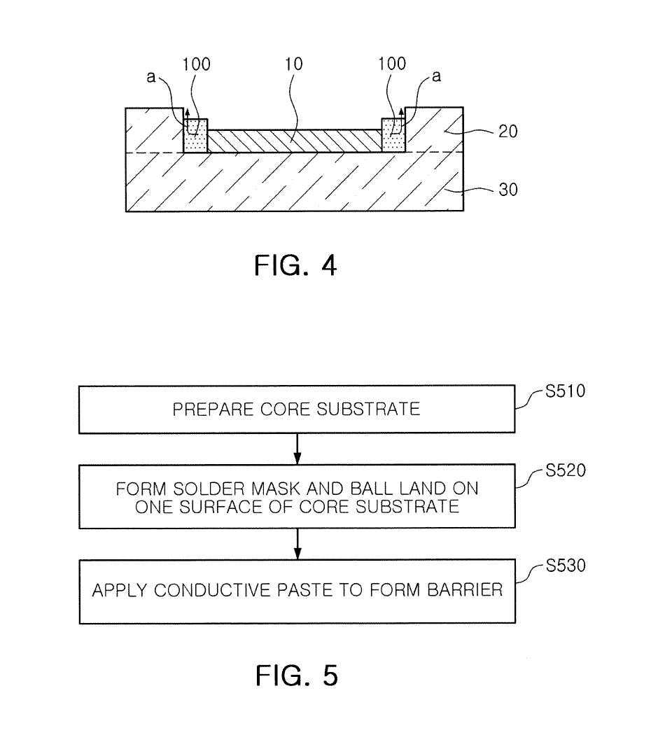

FIG. 4 is a view showing a stress progress direction in a printed circuit board according to the embodiment of the present invention.

In the case in which the solder ball is formed on the SMD-type ball land structure, cracking may occur in the solder mask due to a difference in a coefficient of thermal expansion, a difference in a flexural modulus, or the like, between the solder mask and the solder ball. The reason is that stress at the time of forming the solder ball may be directly applied to the solder mask.

In the case in which the cracking occurring in the solder mask progresses, it may cause an electrical malfunction.

Meanwhile, according to the embodiment of the present invention, in the case in which the solder ball is formed on the ball land 10, the stress occurring in the solder ball may be applied to the barrier 100. In this case, the barrier 100 may absorb the stress occurring at the time of the formation of the solder ball. That is, the solder mask 20 may not be affected by the stress occurring in the solder ball, due to the barrier 100.

As seen in FIG. 4, the occurrence of the stress “a” does not necessarily continue toward the solder mask.

Therefore, the printed circuit board according to the embodiment of the present invention may prevent the cracking from occurring in the solder mask 20.

Meanwhile, even in the case that delamination of the barrier 100 and the ball land 10 occurs, it may not progress in a direction in which the cracking occurs in the solder mask. In this case, the delamination may progress between the barrier 10 and the solder mask 100. In this case, the delamination only progresses in a vertical direction, such that an additional electrical defect phenomenon may not occur.

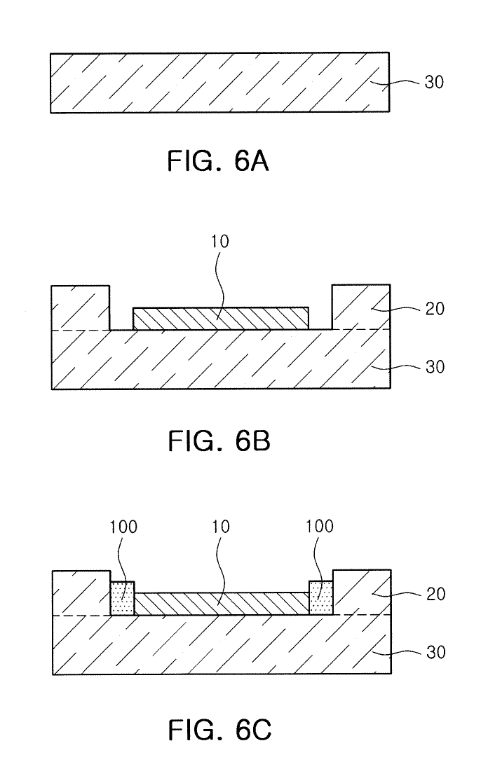

FIG. 5 is a flow chart schematically showing a method of fabricating a printed circuit board according to the embodiment of the present invention, and FIGS. 6A through 6C are cross-sectional views for describing the printed circuit board fabricating method of FIG. 5.

Referring to FIG. 5 through 6C, the method of fabricating the printed circuit board according to the embodiment of the present invention may include preparing a core substrate (S510), as shown in FIG. 6A.

The core substrate 30 maybe formed of a material such as prepreg. The prepreg may be in a semi-hardened state and have excellent adhesive force.

A kind of substrate that may be used as the core substrate 30 is not particularly limited. For example, a substrate having a wiring formed on a surface thereof, such as a lead frame, may be used.

In addition, a type of substrate is not particularly limited. For example, the substrate may include both a panel type core and a reel-type thin film core.

Meanwhile, the method of fabricating the printed circuit board according to the embodiment of the present invention may include forming a solder mask and a ball land on one surface of the core substrate (S520), as shown in FIG. 6B.

Meanwhile, the method of fabricating the printed circuit board according to the embodiment of the present invention may include applying a conductive paste to a region between the solder mask 20 and the ball land 10 to form a barrier (S530), as shown in FIG. 6C.

The conductive paste may include a metal powder having high conductivity. For example, the conductive paste may include a copper (Cu) powder, a silver (Ag) powder, or the like.

The conductive paste may have a viscosity of 10,000 to 30,000 cP.

In the case in which the viscosity of the conductive paste corresponds to the above-mentioned range, since a form of the conductive paste may be maintained in the process of forming the barrier, process efficiency in printing and dispensing processes may be improved.

The conductive paste may have a thixotropic index of 1.5 to 2.0.

In the case in which the thixotropic index of the conductive paste is 1.5 to 2.0, the form of the conductive paste may be maintained in the process of forming the barrier. Therefore, process efficiency in the printing and dispensing processes during the process of forming the barrier may be improved.

According to the embodiment of the present invention, after the conductive paste is applied to the region between the solder mask 20 and the ball land 10, the printing and dispensing processes may be performed.

In this case, the barrier 10 may be formed by performing the printing and dispensing processes.

The printed circuit board formed as described above may reduce the bonding resistance with the solder ball.

In addition, the printed circuit board may prevent the cracking from occurring in the solder mask at the time of forming the solder ball.

As set forth above, according to the embodiment of the present invention, a printed circuit board capable of preventing cracking from occurring in the solder mask may be provided.

In addition, according to the embodiment of the present invention, a printed circuit board capable of increasing electrical connectivity to the solder ball may be provided.

While the present invention has been shown and described in connection with the embodiments, it will be apparent to those skilled in the art that modifications and variations can be made without departing from the spirit and scope of the invention as defined by the appended claims.

What is claimed is:

1. A printed circuit board comprising:
a core substrate;
a solder mask selectively covering one surface of the core substrate;
an open region of the solder mask including a portion of a surface of the core substrate and partitioned by the solder mask;
a ball land formed on the open region of the solder mask; and
a barrier formed between the ball land and the solder mask.

2. The printed circuit board of claim 1, wherein the ball land includes copper (Cu).

3. The printed circuit board of claim 1, wherein a height of the barrier is greater than that of the ball land and less than that of the solder mask.

4. The printed circuit board of claim 1, wherein one side of the barrier contacts the ball land and the other side thereof contacts the solder mask.

5. The printed circuit board of claim 1, wherein the height of the barrier is 10 μm or less.

6. The printed circuit board of claim 1, wherein the barrier includes a conductive metal.

7. A printed circuit board comprising:
a core substrate;
a solder mask formed on one surface of the core substrate;
a ball land formed on one surface of the core substrate; and
a barrier formed between the solder mask and the ball land and including a conductive metal.

8. The printed circuit board of claim 7, wherein a height of the barrier is greater than that of the ball land and less than that of the solder mask.

9. A method of fabricating a printed circuit board, comprising:
preparing a core substrate;
forming a solder mask and a ball land on one surface of the core substrate; and
applying a conductive paste between the solder mask and the ball land to form a barrier.

10. The method of claim 9, wherein the conductive paste includes at least one of a copper (Cu) powder and a silver (Ag) powder.

11. The method of claim 9, wherein the conductive paste has a viscosity of 10,000 to 30,000 cP.
